(19) United States
(12) Patent Application Publication
(10) Pub. No.: US 2026/0271334 A1
(43) Pub. Date: Sep. 10, 2026

(54) STRIPE TYPE SEMICONDUCTOR CELL STRUCTURE AND SEMICONDUCTOR DEVICE

(71) Applicant: Taipei ANJET Corporation, Taipei (TW)

(72) Inventors: Yasuo Kitahira, Kyoto-city (JP); Yuji Kiuchi, Kyoto-city (JP); Cheng Hou Chan, Kyoto-city (JP); Wen-Chin WU, Taipei City (TW)

(21) Appl. No.: 19/071,815

(22) Filed: Mar. 6, 2025

(51) Int. Cl. H10D 30/66

(52) U.S. Cl. CPC H10D 30/662

(57) ABSTRACT

Disclosed is a stripe type semiconductor cell structure including a semiconductor body, a stripe-shaped gate structure and a drain electrode on opposite surfaces of the semiconductor body. The semiconductor body includes a drift layer of a first conductivity type, a current spreading layer of the first conductivity type on the drift layer, two well regions of a second conductivity type in the current spreading layer, a JFET region of the first conductivity type between the two well regions, two source regions of the first conductivity type and two stripe-shaped body contact regions of the second conductivity type in the two well regions, and two stripe-shaped doping regions of the second conductivity type underneath the two stripe-shaped body contact regions and at a boundary between the drift layer and the current spreading layer, wherein the two stripe-shaped body contact regions connect at least a portion of the two stripe-shaped doping regions.

### TECHNICAL FIELD

The present disclosure relates to a semiconductor cell structure, and in particular to a stripe type semiconductor cell structure and a semiconductor device.

### RELATED ART

In a metal-oxide-semiconductor field-effect transistor (MOSFET) device, which includes a gate electrode, a drain electrode and a source electrode, there are capacitors between three electrodes, i.e., a capacitance Cgs between the gate electrode and the source electrode, a capacitance Cgd between the gate electrode and the drain electrode and a capacitance Cds between the drain electrode and the source electrode. The sum of the capacitance Cgd and the capacitance Cgs is taken as an input capacitance Ciss, the sum of the capacitance Cds and the capacitance Cgd is taken as an output capacitance Coss, and the capacitance Cgd is taken as a reverse transfer capacitance Crss, wherein the output capacitance Coss determine the efficiency of the MOSFET device by affecting the increase in switching time. In other words, as the output capacitance Coss increases, the time necessary for charging or discharging the output capacitance Coss when switching the MOSFET device lengthens. Therefore, it is desirable to reduce the output capacitance Coss.

However, as the cell-pitch in the MOSFET device becomes finer to reduce the on-resistance Ron, the source area increases, which causes an increase in the output capacitance Coss.

### SUMMARY

The present disclosure provides a stripe type semiconductor cell structure and semiconductor device, which can solve the problem of the increase in the output capacitance Coss caused by the increase in the source area due to a cell shrink.

In order to solve the above technical problem, the present disclosure is implemented as follows.

In an aspect of the present disclosure, the present disclosure provides a stripe type semiconductor cell structure, which includes a semiconductor body, a stripe-shaped gate structure on the semiconductor body and a drain electrode. The semiconductor body includes a drift layer of a first conductivity type, a current spreading layer of the first conductivity type, spaced apart two well regions of a second conductivity type opposite to the first conductivity type, a junction gate field-effect transistor (JFET) region of the first conductivity type, two source regions of the first conductivity type, two stripe-shaped body contact regions of the second conductivity type and two stripe-shaped doping regions of the second conductivity type, wherein the current spreading layer is arranged on the drift layer, the two well regions are arranged in the current spreading layer, the JFET region is arranged in the current spreading layer and defined between the two well regions, the two source regions are respectively disposed in the two well regions, the two stripe-shaped body contact regions are respectively disposed in the two well regions, the two stripe-shaped doping regions correspond to the two stripe-shaped body contact regions, the two stripe-shaped doping regions are disposed underneath the two stripe-shaped body contact regions respectively, the two stripe-shaped doping regions are arranged at a boundary between the drift layer and the current spreading layer, and the two stripe-shaped body contact regions are connected to at least a portion of the two stripe-shaped doping regions corresponding thereto. The stripe-shaped gate structure is arranged over the JFET region and at least portions of the two source regions. The drain electrode is in contact with a surface of the semiconductor body away from the stripe-shaped gate structure.

In another aspect of the present disclosure, the present disclosure provides a semiconductor device, which includes a plurality of stripe type semiconductor cell structures of the present disclosure. In each stripe type semiconductor cell structure, the two stripe-shaped body contact regions are located under the two source regions corresponding thereto; the semiconductor body further includes two alternating strips of first doped regions and second type doped regions; the two alternating strips are disposed in the two well regions respectively and on the two stripe-shaped body contact regions corresponding thereto, and are adjacent to the two source regions corresponding thereto; the first doped regions of one of the two alternating strips and the first doped regions of another of the two alternating strips are arranged in a zigzag pattern, and the second doped regions of one of the two alternating strips and the second doped regions of another of the two alternating strips are arranged in a zigzag pattern. The adjacent stripe type semiconductor cell structures are arranged in a mirror image manner in a vertical direction.

According to the present disclosure, by the disposition of the two stripe-shaped doping regions in the stripe type semiconductor cell structure (that is, the two stripe-shaped doping regions are disposed underneath the two stripe-shaped body contact regions respectively, the two stripe-shaped doping regions are arranged at a boundary between the drift layer and the current spreading layer, and the two stripe-shaped body contact regions are connected to at least a portion of the two stripe-shaped doping regions corresponding thereto), the output capacitance Coss of the stripe type semiconductor cell structure, which is linked to the extension of the depletion layer in the current spreading layer, is reduced when the drain-source voltage (Vds) is low. Besides, by the zigzag patterns of the first doped regions and the second doped regions of the two alternating strips in the stripe type semiconductor cell structure and the configuration design of the adjacent stripe type semiconductor cell structures (that is, the adjacent stripe type semiconductor cell structures are arranged in a mirror image manner in the vertical direction), the semiconductor device and the stripe type semiconductor cell structure of the present disclosure can be provided with a uniform current distribution.

It should be understood, however, that this summary may not contain all aspects and embodiments of the present disclosure, that this summary is not meant to be limiting or restrictive in any manner, and that the disclosure as disclosed herein will be understood by one of ordinary skill in the art to encompass obvious improvements and modifications thereto.

### BRIEF DESCRIPTION OF THE DRAWINGS

The features of the exemplary embodiments believed to be novel and the elements and/or the steps characteristic of the exemplary embodiments are set forth with particularity in the appended claims. The Figures are for illustration purposes only and are not drawn to scale. The exemplary embodiments, both as to organization and method of operation, may best be understood by reference to the detailed description which follows taken in conjunction with the accompanying drawings in which:

FIG. 1 is a schematic cross-sectional view of a stripe type semiconductor cell structure according to a first embodiment of the present disclosure;

FIG. 2 is a schematic cross-sectional view of a stripe type semiconductor cell structure according to a second embodiment of the present disclosure;

FIG. 3 is a schematic cross-sectional view of a stripe type semiconductor cell structure according to a third embodiment of the present disclosure;

FIG. 4 is a schematic cross-sectional view of a stripe type semiconductor cell structure according to a fourth embodiment of the present disclosure;

FIG. 5 is a schematic cross-sectional view of a stripe type semiconductor cell structure according to a fifth embodiment of the present disclosure;

FIG. 6 is a schematic cross-sectional view of a stripe type semiconductor cell structure according to a sixth embodiment of the present disclosure;

FIG. 7 is a schematic cross-sectional view of a stripe type semiconductor cell structure according to a seventh embodiment of the present disclosure;

FIG. 8 is a schematic cross-sectional view of a stripe type semiconductor cell structure according to an eighth embodiment of the present disclosure;

FIG. 9 is a schematic cross-sectional view of a stripe type semiconductor cell structure according to a ninth embodiment of the present disclosure;

FIG. 10 is a schematic cross-sectional view of a stripe type semiconductor cell structure according to a tenth embodiment of the present disclosure;

FIG. 11 is a schematic cross-sectional view of a stripe type semiconductor cell structure according to an eleventh embodiment of the present disclosure;

FIG. 12 is a schematic cross-sectional view of a stripe type semiconductor cell structure according to a twelfth embodiment of the present disclosure;

FIG. 13 is a schematic top view of the stripe type semiconductor cell structure without the source electrodes of each of FIG. 11 and FIG. 12;

FIG. 14 is a schematic cross-sectional view of a semiconductor device according to a first embodiment of the present disclosure;

FIG. 15 is a schematic cross-sectional view of a semiconductor device according to a second embodiment of the present disclosure;

FIG. 16 is a schematic cross-sectional view of the stripe type semiconductor cell structure of FIG. 5 without the two stripe-shaped doping regions;

FIG. 17 is a diagram illustrating output capacitance versus drain-source voltage in the stripe type semiconductor cell structures of FIG. 5, FIG. 6, and FIG. 16.

### DETAILED DESCRIPTION OF THE EMBODIMENTS

The present disclosure will now be described more fully hereinafter with reference to the accompanying drawings, in which exemplary embodiments of the disclosure are shown. This present disclosure may, however, be embodied in many different forms and should not be construed as limited to the embodiments set forth herein. Rather, these embodiments are provided so that this present disclosure will be thorough and complete, and will fully convey the scope of the present disclosure to those skilled in the art.

In the following description and in the claims, the terms “include/including” and “comprise/comprising” are used in an open-ended fashion, and thus should be interpreted as “including but not limited to”. Therefore, a process, method, object, or device that includes a series of elements not only includes these elements, but also includes other elements not specified expressly, or may include inherent elements of the process, method, object, or device.

It must be understood that when a component is described as being “connected” or “coupled” to (or with) another component, it may be directly connected or coupled to other components or through an intermediate component. In contrast, when a component is described as being “directly connected” or “directly coupled” to (or with) another component, there are no intermediate components.

In the specification, the regions and layers prefixed by “n” or “p” contain the majority carriers of electrons or holes, respectively. The symbol “+” or “−” added to the “n” and “p” means relatively high or low impurity concentration in the region or layer.

In the following embodiment, the same reference numerals are used to refer to the same or similar elements throughout the disclosure.

In the following description and the accompanying drawings, the orientations of the stripe type semiconductor cell structure and the semiconductor device may be defined by the XYZ axis directions. For example, in the cross-sectional view, the lateral direction may be in the X axis direction, the vertical direction may be in the Z axis direction, and the direction perpendicular to the XZ plane may be in the Y axis direction, wherein the Y axis direction is an extension direction of a stripe type semiconductor cell structure.

Referring to FIG. 1, which is a schematic cross-sectional view of a stripe type semiconductor cell structure according to a first embodiment of the present disclosure. A stripe type semiconductor cell structure 100 comprises a semiconductor body 110, a stripe-shaped gate structure 120 on the semiconductor body 110 and a drain electrode 130. In this embodiment of the present disclosure, the semiconductor cell structure may be a double-diffused metal-oxide-semiconductor (DMOS) cell structure. In the following, the DMOS cell structure is a vertical DMOS cell structure, for example.

The semiconductor body 110 can comprise a semiconductor substrate layer 111 of a first conductivity type, a drift layer 112 of the first conductivity type, a current spreading layer 113 of the first conductivity type, two well regions 114 of a second conductivity type opposite to the first conductivity type, a junction gate field-effect transistor (JFET) region 115 of the first conductivity type, two source regions 116 of the first conductivity type, two stripe-shaped body contact regions 117 of the second conductivity type and two stripe-shaped doping regions 118 of the second conductivity type, wherein the first conductivity type is an n-type conductivity type, and the second conductivity type is a p-type conductivity type.

The semiconductor substrate layer 111 may comprise various semiconductor elements, such as silicon or silicon-germanium of a monocrystalline, polycrystalline or noncrystalline structure, and can also include a hybrid semiconductor structure, such as a silicon carbide semiconductor, a gallium nitride semiconductor, an indium phosphide semiconductor, a gallium arsenide semiconductor, an alloy semiconductor or a combination thereof, which is not limited herein. In addition, the semiconductor substrate layer 111 is doped with n-type impurities to an “n+” concentration.

The drift layer 112 may be epitaxially grown on the semiconductor substrate layer 111 by, for example, a chemical vapor deposition process. In addition, the drift layer 112 is doped with n-type impurities to an “n−” concentration to indicate that the semiconductor substrate layer 111 are more heavily doped than the semiconductor substrate layer 111.

The current spreading layer 113 is arranged on the drift layer 112. The current spreading layer 113 may be made with implantation, and may be epitaxially grown on the drift layer 112 by, for example, a chemical vapor deposition process. The current spreading layer 113 is doped with n-type impurities to an “n” concentration, and the concentration of the n-type impurities of the current spreading layer 113 is greater than the concentration of the n-type impurities of the drift layer 112. For example, the doping concentration of the current spreading layer 113 can be 1×10¹⁶ cm⁻³ to 1×10¹⁷ cm⁻³, and the doping concentration of the drift layer 112 can be 5×10¹⁵ cm⁻³ to 2×10¹⁶ cm⁻³.

The two well regions 114, which are spaced apart from each other, are formed in an upper layer part of the current spreading layer 113 (that is, the two well regions 114 are arranged in the current spreading layer 113) and reach the upper surface 110a of the semiconductor body 110. Further, a depth (a thickness) of the well region 114 is smaller than the thickness of the current spreading layer 113. Hence, the two well regions 114 are apart from the drift layer 112.

The current spreading layer 113 reaches the upper surface 110a of the semiconductor body 110 at a part between the two well regions 114, and a part sandwiched between the two well regions 114 in the current spreading layer 113 is the JFET region 115 (that is, the JFET region 115 is arranged in the current spreading layer 113 and defined between the two well regions 114). Further, The JFET region 115 has a width WJ on the upper surface 110a of the semiconductor body 110 in a direction in which the two well regions 114 are adjacent to each other (i.e., the X axis direction in FIG. 1). The two well regions 114 are doped with p-type impurities to a “p” concentration whereas the JFET region 115 is doped with n-type impurities to an “n” concentration. The depth and impurity profile of the JFET region 115 can be adjusted according to actual needs.

The two source regions 116 are respectively disposed in the two well regions 114 and reach the upper surface 110a of the semiconductor body 110. Further, a depth (a thickness) of the source region 116 is smaller than the thickness of the well region 114. Hence, the source region 116 is also apart from the current spreading layer 113 under the well region 114. The two source regions 116 are doped with n-type impurities to a “n+” concentration.

The two stripe-shaped body contact regions 117 are respectively disposed in the two well regions 114 and reach the upper surface 110a of the semiconductor body 110. The stripe-shaped body contact region 117 is formed adjacent to the source region 116, and a depth (a thickness) of the stripe-shaped body contact region 117 is smaller than the thickness of the well region 114. Further, the stripe-shaped body contact region 117 is doped with p-type impurities to a “p+” concentration.

As illustrated in FIG. 1, an upper surface of the JFET region 115, upper surfaces of the two well regions 114, upper surfaces of the two source regions 116, and upper surfaces of the two stripe-shaped body contact regions 117 are included in the upper surface 110a of the semiconductor body 110.

The two stripe-shaped doping regions 118 correspond to the two stripe-shaped body contact regions 117. Specially, the two stripe-shaped doping regions 118 are disposed underneath the two stripe-shaped body contact regions 117 respectively, the two stripe-shaped doping regions 118 are arranged at a boundary between the drift layer 112 and the current spreading layer 113, and the two stripe-shaped body contact regions 117 are connected to at least a portion of the two stripe-shaped doping regions 118 corresponding thereto. Further, the stripe-shaped doping regions 118 is doped with p-type impurities to a “p+” concentration, and the concentration of the p-type impurities of the stripe-shaped body contact region 117 is higher than the concentration of the p-type impurities of the stripe-shaped doping region 118.

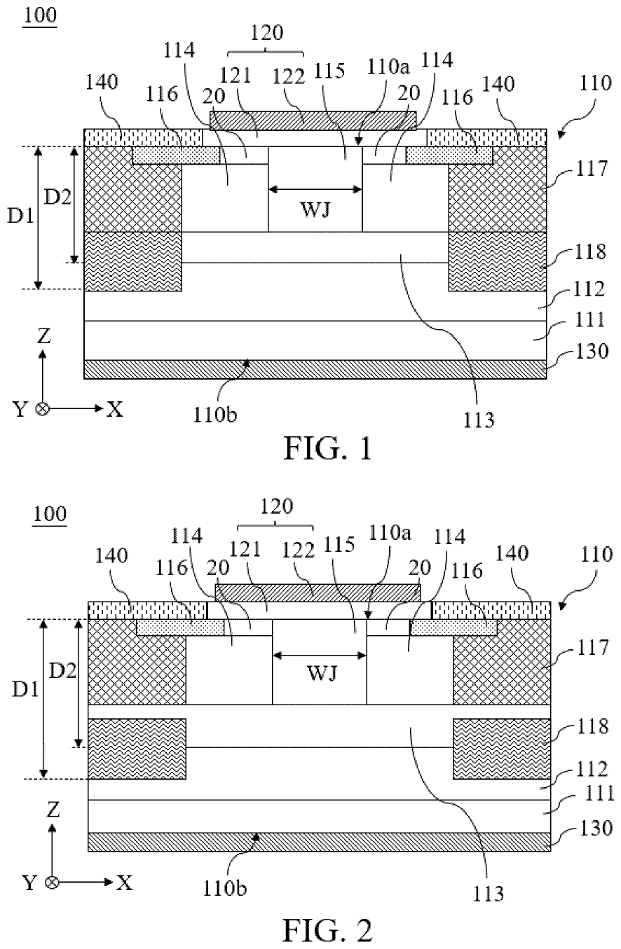

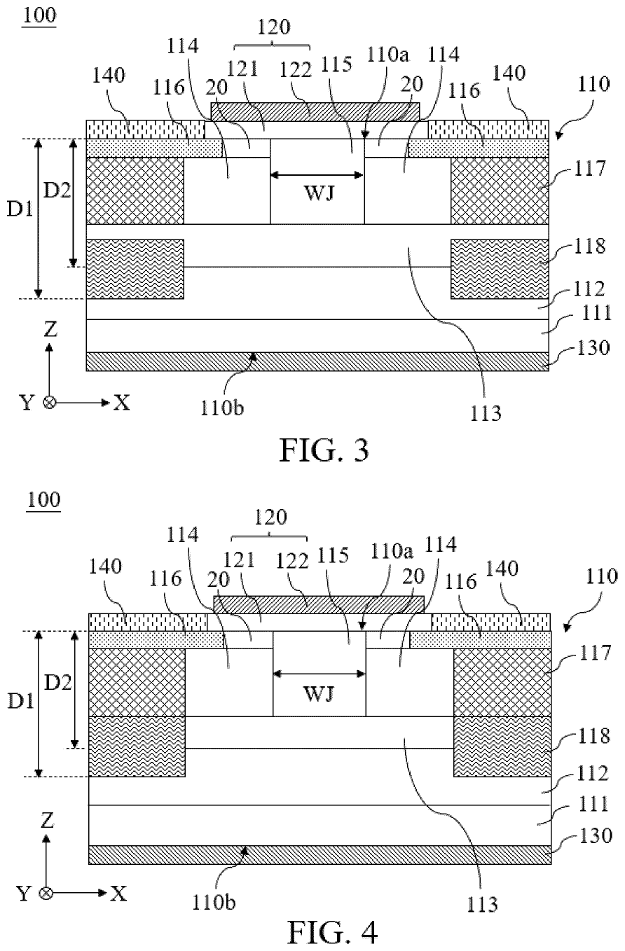

In this embodiment, the two stripe-shaped doping regions 118 are disposed under the two stripe-shaped body contact regions 117 respectively, and the two stripe-shaped body contact regions 117 are fully connected to the two stripe-shaped doping regions 118 corresponding thereto, which is not intended to limit the present disclosure. In some embodiments, as illustrated in FIG. 2 and FIG. 3, FIG. 2 is a schematic cross-sectional view of a stripe type semiconductor cell structure according to a second embodiment of the present disclosure, FIG. 3 is a schematic cross-sectional view of a stripe type semiconductor cell structure according to a third embodiment of the present disclosure. The two stripe-shaped doping regions 118 are located below the two stripe-shaped body contact regions 117 respectively, and the two stripe-shaped body contact regions 117 are connected to at least a portion of the two stripe-shaped doping regions 118 corresponding thereto. It should be noted that the peripheral of the stripe-shaped doping region 118 (i.e., the end of the stripe-shaped doping region 118 extending along the Y-axis direction) is connected to the stripe-shaped body contact region 117 corresponding thereto, so as to make the stripe-shaped doping region 118 and the stripe-shaped body contact region 117 corresponding thereto have the same potential.

The stripe-shaped gate structure 120 are arranged over the JFET region 114 and at least portions of the two source regions 115. That is, the stripe-shaped gate structure 120 is in contact with part of the upper surface 110a of the semiconductor body 110. In the present exemplary embodiment, the stripe-shaped gate structure 120 comprises a gate dielectric layer 121 arranged over the JFET region 115 and the at least portions of the two source regions 116, and a gate electrode 122 disposed on the gate dielectric layer 121. The width (i.e., the length in the X axis direction) of the gate dielectric layer 121 is equal to or greater than the width (i.e., the length in the X axis direction) of gate electrode 122. For example, the gate dielectric layer 121 is made of silicon oxide (SiO₂), and the gate electrode 7 is made of polysilicon (poly-Si).

The drain electrode 130 is in contact with a surface of the semiconductor body 110 away from the stripe-shaped gate structure 120 (i.e., the lower surface 110b of the semiconductor body 110). The drain electrode 130 is an electrode forming an ohmic junction with the semiconductor body 110. For example, the drain electrode 130 is made of an alloy of titanium (Ti) and silicon (Si).

To reduce the on-resistance of the stripe type semiconductor cell structure 100 the doping concentration of the current spreading layer 113 is higher than the doping concentration of the drift layer 112. However, the depletion layer does not spread as much if the stripe type semiconductor cell structure 100 does not comprise the two stripe-shaped doping regions 118, thereby increasing the output capacitance Coss when the drain-source voltage (Vds) is low. Thus, in the configuration of the stripe type semiconductor cell structure 100, the stripe type semiconductor cell structure 100 comprises the two stripe-shaped doping regions 118, wherein the two stripe-shaped doping regions 118 are disposed underneath the two stripe-shaped body contact regions 117 respectively, the two stripe-shaped doping regions 118 are arranged at a boundary between the drift layer 112 and the current spreading layer 113, and the two stripe-shaped body contact regions 117 are connected to at least a portion of the two stripe-shaped doping regions 118 corresponding thereto, so that the depletion layer at the p-n junction between the stripe-shaped doping region 118 and the drift layer 112 (i.e., the extension of the depletion layer in the current spreading layer 113) can reduce the output capacitance Coss when the Vds is low.

In addition, the stripe-shaped doping regions 118 and the stripe-shaped body contact regions 117 extend along the Y axis direction (that is, the stripe-shaped doping regions 118 and the stripe-shaped body contact regions 117 are in the line shapes), so no corners are formed, thereby avoiding the risk of a decrease in breakdown voltage in the corners.

According to some embodiments, referring to FIG. 1 and FIG. 2, the two stripe-shaped body contact regions 117 surround a portion of the two source regions 116 corresponding thereto. According to some embodiments, referring to FIG. 3 and FIG. 4, FIG. 4 is a schematic cross-sectional view of a stripe type semiconductor cell structure according to a fourth embodiment of the present disclosure, the two source regions 116 cover the two stripe-shaped body contact regions 117 corresponding thereto.

According to some embodiments, each well region 114 comprises a channel area 20, which is disposed under the stripe-shaped gate structure 120 and next to the source region 116 of the same well region 114 and the JFET region 115; the two stripe-shaped doping regions 118 are not underneath the two channel areas 20, as shown in FIG. 1 to FIG. 4, wherein when a voltage is applied to the gate electrode 7, the channel area 20 is an inversion layer, which appears on the surface of the well region 114 facing the gate electrode 7 and is used to create a path for current to flow. Since the two stripe-shaped doping regions 118 are not underneath the two channel areas 20, and the two stripe-shaped doping regions 118 are disposed underneath the two stripe-shaped body contact regions 117 respectively, the mask used to form the two stripe-shaped doping regions 118 by ion implantation is the same as the mask used to form the two strip-shaped doping regions 118 by ion implantation, thereby eliminating the need for additional mask.

According to some embodiments, a depth D1 of each stripe-shaped doping region 118 is greater than a depth D2 of the current spreading layer 113, as shown in FIG. 1 to FIG. 4. In other words, the maximum distance from the stripe-shaped doping region 118 to the upper surface 110a of the semiconductor body 110 in the Z axis direction is greater than the maximum distance from the current spreading layer 113 to the upper surface 110a of the semiconductor body 110 in the Z axis direction. For example, the depth D1 of each stripe-shaped doping region 118 can be 1.0 micrometer (μm) to 1.5 μm, and the depth D2 of the current spreading layer 113 can be 0.8 μm to 1.0 μm.

According to some embodiments, a doping concentration of each stripe-shaped doping region 118 is higher than a doping concentration of the current spreading layer 113, and the doping concentration of each stripe-shaped doping region 118 is lower than a doping concentration of each stripe-shaped body contact region 117. Further, the doping concentration of each stripe-shaped doping region 118 is higher than a doping concentration of the drift layer 112. For example, the doping concentration of each stripe-shaped doping region 118 can be 1×10¹⁷ cm⁻³ to 1×10¹⁸ cm⁻³, the doping concentration of the current spreading layer 113 can be 1×10¹⁶ cm⁻³ to 1×10¹⁷ cm⁻³, the doping concentration of each stripe-shaped body contact region 117 can be 1×10¹⁹ cm⁻³ to 1×10²⁰ cm⁻³, and the doping concentration of the drift layer 112 can be 5×10¹⁵ cm⁻³ to 2×10¹⁶ cm⁻³.

According to some embodiments, portions of the current spreading layer 113 is interposed between portions of the two stripe-shaped doping region 118 where they are not connected to the two stripe-shaped body contact regions 117 and the two stripe-shaped body contact regions 117 corresponding thereto, as shown in FIG. 2 and FIG. 3.

According to some embodiments, the stripe type semiconductor cell structure 100 further comprises two source electrodes 140 formed on the upper surface 110a of the semiconductor body 110 and in contact with the two source regions 116, as shown in FIG. 3 and FIG. 4, wherein the source electrode 140 is an electrode forming an ohmic junction with the source region 116. In some embodiments, the source electrode 140 is further in contact with the stripe-shaped body contact region 117, as shown in FIG. 1 and FIG. 2.

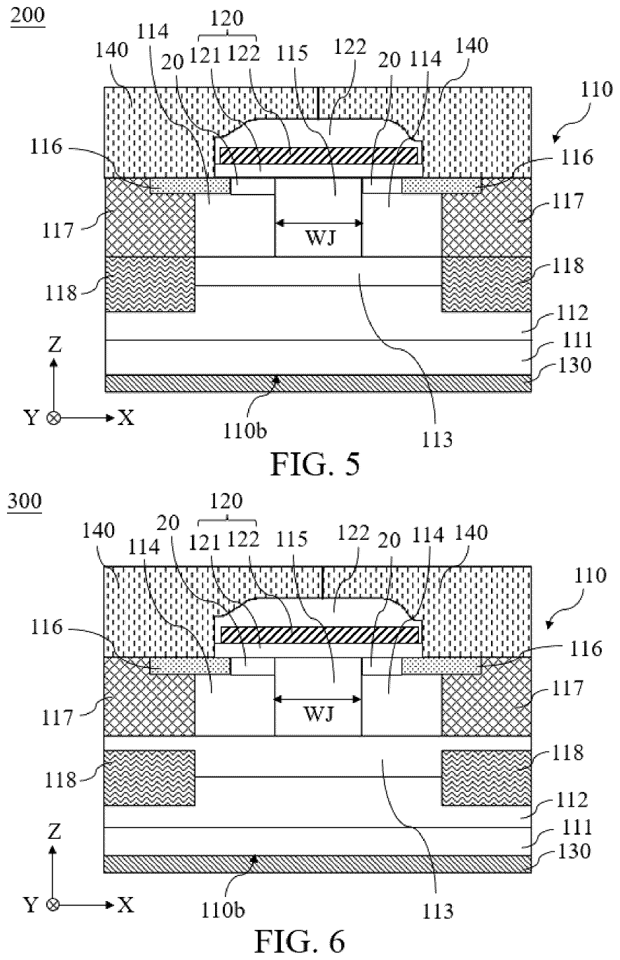

Referring to FIG. 1, FIG. 2, FIG. 5 and FIG. 6, FIG. 5 is a schematic cross-sectional view of a stripe type semiconductor cell structure according to a fifth embodiment of the present disclosure, and FIG. 6 is a schematic cross-sectional view of a stripe type semiconductor cell structure according to a sixth embodiment of the present disclosure. The differences between a stripe type semiconductor cell structure 200 of FIG. 5 and the stripe type semiconductor cell structure 100 of FIG. 1 and the differences between a stripe type semiconductor cell structure 300 of FIG. 6 and the stripe type semiconductor cell structure 100 of FIG. 2 are that in FIG. 5 and FIG. 6, the stripe-shaped gate structure 120 further comprises an insulating layer 123 covering the gate electrode 122 (that is, the insulating layer 123 and the gate dielectric layer 121 surrounds the gate electrode 122), and the two source electrodes 140 can be connected to each other and cover the insulating layer 123, wherein the insulating layer 123 insulates the gate electrode 122 from the two source electrodes 140. For example, the insulating layer 123 is made of silicon oxide, and the source electrode 140 is made of an alloy of titanium (Ti) and silicon (Si).

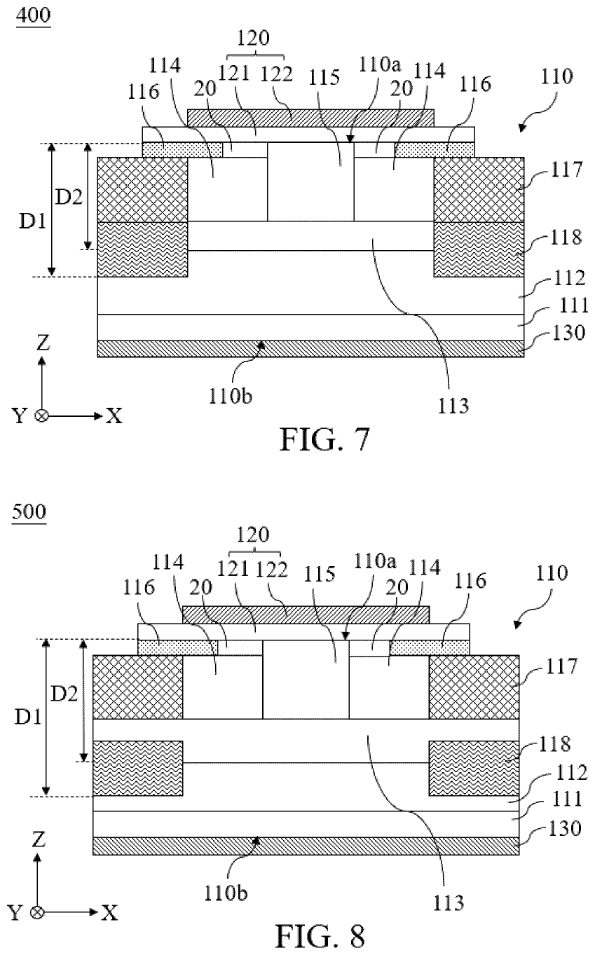

Referring to FIG. 1, FIG. 2, FIG. 7 and FIG. 8, FIG. 7 is a schematic cross-sectional view of a stripe type semiconductor cell structure according to a seventh embodiment of the present disclosure, and FIG. 8 is a schematic cross-sectional view of a stripe type semiconductor cell structure according to an eighth embodiment of the present disclosure. The differences between a stripe type semiconductor cell structure 400 of FIG. 7 and the stripe type semiconductor cell structure 100 of FIG. 1 and the differences between a stripe type semiconductor cell structure 500 of FIG. 8 and the stripe type semiconductor cell structure 100 of FIG. 2 are that in FIG. 7 and FIG. 8, the two stripe-shaped body contact regions 117 are located under the two source regions 116 corresponding thereto, the gate dielectric layer 121 is arranged over the two source regions 116, and the width of the gate dielectric layer 121 is greater than the width of gate electrode 122 (that is, the stripe-shaped gate structure 120 is arranged over the two source regions 116). Since the gate dielectric layer 121 is arranged over the two source regions 116, and the width of the gate dielectric layer 121 is greater than the width of gate electrode 122, the channel can be shortened to reduce the lateral spread. In addition, the two source regions 116 are connected to the two stripe-shaped body contact regions 117, and the two source regions 116 are etched to expose the two stripe-shaped body contact regions 117.

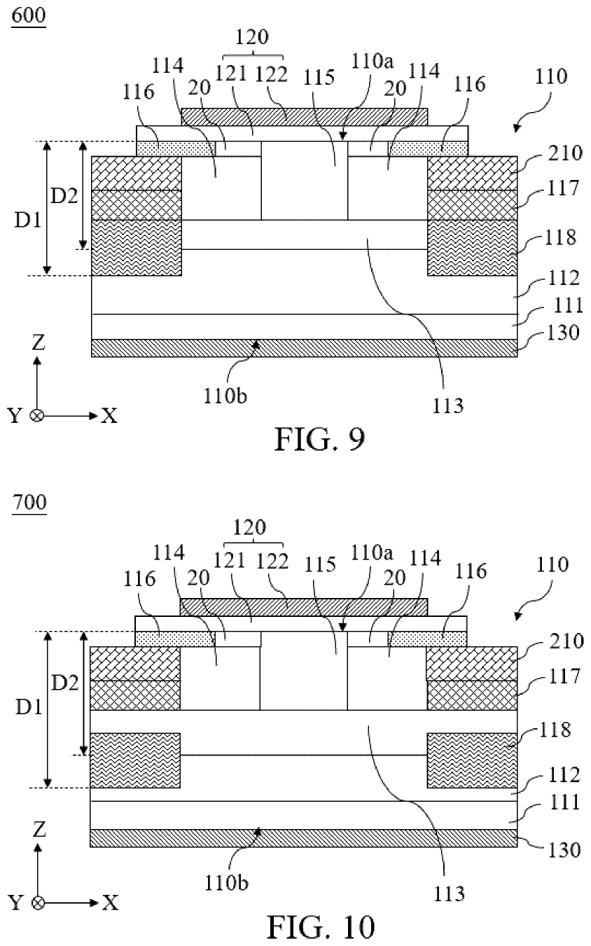

Referring to FIG. 7 to FIG. 10, FIG. 9 is a schematic cross-sectional view of a stripe type semiconductor cell structure according to a ninth embodiment of the present disclosure, and FIG. 10 is a schematic cross-sectional view of a stripe type semiconductor cell structure according to a tenth embodiment of the present disclosure. The differences between the stripe type semiconductor cell structure 400 of FIG. 7 and a stripe type semiconductor cell structure 600 of FIG. 9 and the differences between the stripe type semiconductor cell structure 500 of FIG. 8 and a stripe type semiconductor cell structure 700 of FIG. 10 are that in FIG. 9 and FIG. 10, the semiconductor body 110 further comprises two auxiliary doping source regions 210 of the first conductivity type respectively disposed in the two well regions 114 and located under the two source regions 116 respectively, and the two stripe-shaped body contact regions 117 are located under the two auxiliary doping source regions 210 respectively. The two auxiliary doping source regions 210 are configured to achieve ohmic contact. Besides, the auxiliary doping source regions 210 and the stripe-shaped body contact regions 117 are configured to stabilize the breakdown voltage.

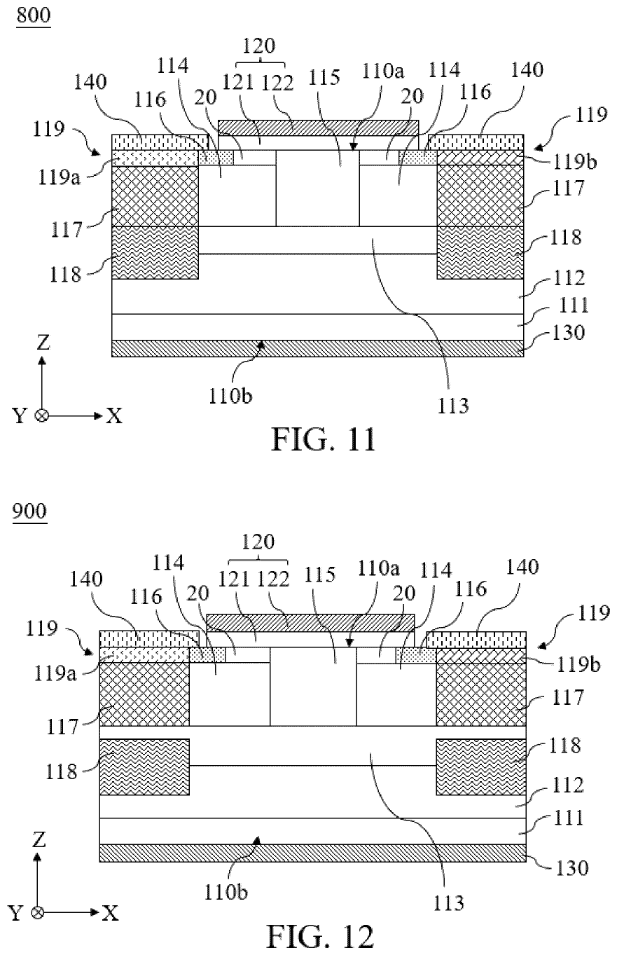

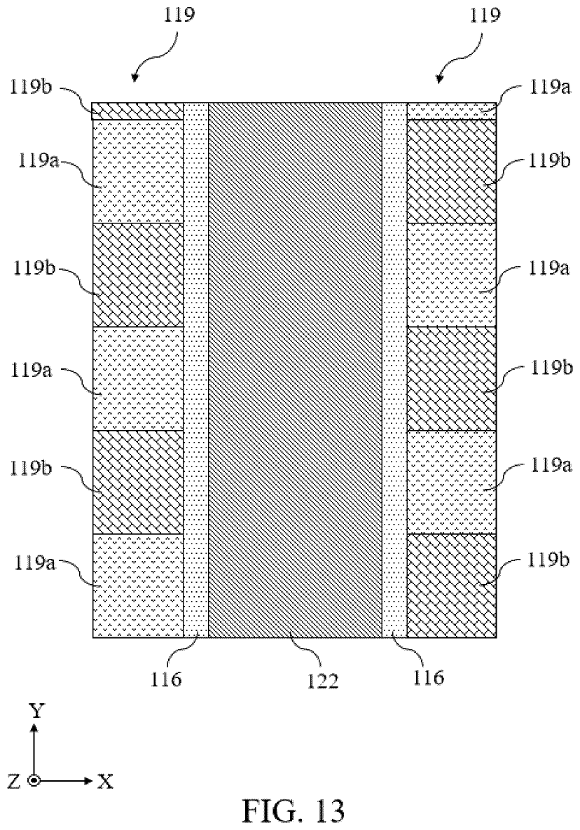

Referring to FIG. 1, FIG. 2, FIG. 11 and FIG. 12, FIG. 11 is a schematic cross-sectional view of a stripe type semiconductor cell structure according to an eleventh embodiment of the present disclosure, and FIG. 12 is a schematic cross-sectional view of a stripe type semiconductor cell structure according to a twelfth embodiment of the present disclosure. The differences between the stripe type semiconductor cell structure 100 of FIG. 1 and a stripe type semiconductor cell structure 800 of FIG. 11 and the differences between the stripe type semiconductor cell structure 100 of FIG. 2 and a stripe type semiconductor cell structure 900 of FIG. 12 are that in FIG. 11 and FIG. 12, the two stripe-shaped body contact regions 117 are located under the two source regions 116 corresponding thereto, the semiconductor body 110 further comprises two alternating strips 119 of first doped regions 119a and second type doped regions 119b, wherein the two alternating strips 119 are disposed in the two well regions 114 respectively and on the two stripe-shaped body contact regions 117 corresponding thereto, and are adjacent to the two source regions 116 corresponding thereto, as shown in FIG. 13, which is a schematic top view of the stripe type semiconductor cell structure without the source electrodes of each of FIG. 11 and FIG. 12. Further, in FIG. 11 and FIG. 12, the first doped regions 119a of one of the two alternating strips 119 and the first doped regions 119a of another of the two alternating strips 119 are arranged in a zigzag pattern, and the second doped regions 119b of one of the two alternating strips 119 and the second doped regions 119b of another of the two alternating strips 119 are arranged in a zigzag pattern. Thus, the stripe type semiconductor cell structure 800 and the stripe type semiconductor cell structure 900 can be provided with a uniform current distribution.

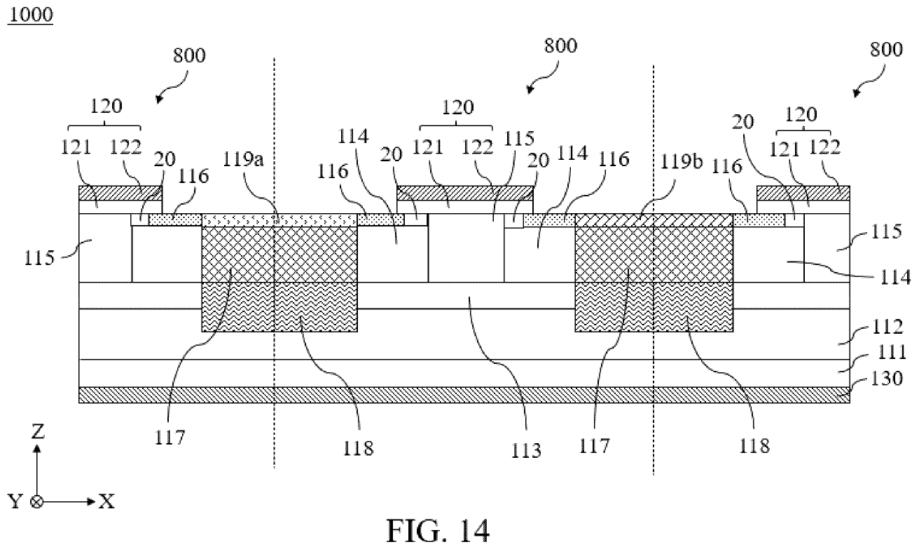

Referring to FIG. 14, which is a schematic cross-sectional view of a semiconductor device according to a first embodiment of the present disclosure. A semiconductor device 1000 comprises a plurality of the stripe type semiconductor cell structures 800 of FIG. 11 without the source electrodes 140, and adjacent stripe type semiconductor cell structures 800 are arranged in a mirror image manner in a vertical direction (i.e. X axis direction). The number of the stripe type semiconductor cell structures 800 can be adjusted according to actual needs. By the design of the two alternating strips 119 of the stripe type semiconductor cell structure 800, the semiconductor device 1000 can be provided with a uniform current distribution.

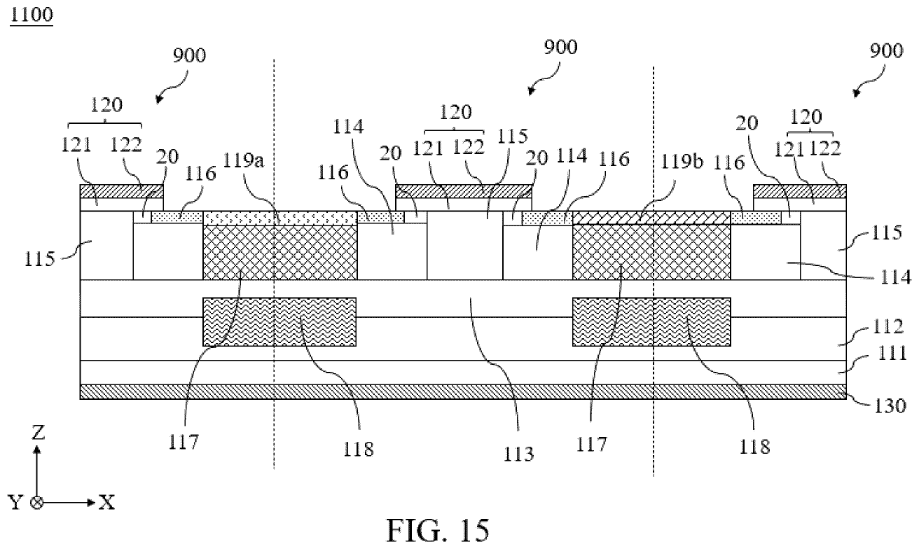

Referring to FIG. 15, which is a schematic cross-sectional view of a semiconductor device according to a second embodiment of the present disclosure. A semiconductor device 1100 comprises a plurality of the stripe type semiconductor cell structures 900 of FIG. 12 without the source electrodes 140, and adjacent stripe type semiconductor cell structures 900 are arranged in a mirror image manner in a vertical direction (i.e. X axis direction). The number of the stripe type semiconductor cell structures 900 can be adjusted according to actual needs. By the design of the two alternating strips 119 of the stripe type semiconductor cell structure 900, the semiconductor device 1100 can be provided with a uniform current distribution.

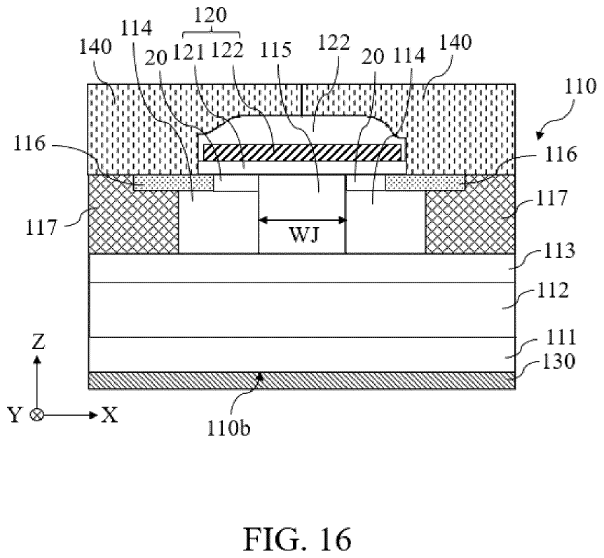

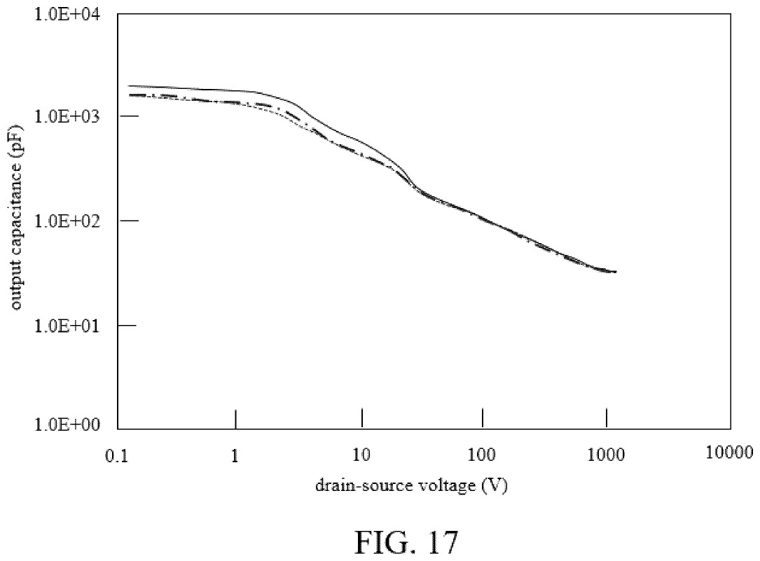

Referring to FIG. 5, FIG. 6, FIG. 16, and FIG. 17, FIG. 16 a schematic cross-sectional view of the stripe type semiconductor cell structure of FIG. 5 without the two stripe-shaped doping regions, and FIG. 17 is a diagram illustrating output capacitance versus drain-source voltage in the stripe type semiconductor cell structures of FIG. 5, FIG. 6, and FIG. 16. In FIG. 16, a stripe type semiconductor cell structure 10 is the stripe type semiconductor cell structure 200 of FIG. 5 without the two stripe-shaped doping regions 118. In FIG. 17, a solid line is the curve showing output capacitance versus drain-source voltage in the stripe type semiconductor cell structure 10 of FIG. 16, a dotted line is the curve showing output capacitance versus drain-source voltage in the stripe type semiconductor cell structure 200 of FIG. 5, and a thick chain line is the curve showing output capacitance versus drain-source voltage in the stripe type semiconductor cell structure 300 of FIG. 6. It should be appreciated that the solid line, the dotted line and the thick chain line partial overlap.

In FIG. 5 and FIG. 6, the width WJ of the JFET region 115 is 1.2 μm, the concentration of the JFET region 115 doped with n-type impurities is 7.5×10¹² cm⁻³, the width of the well region 114 is 1 μm, and the width of the stripe-shaped doping region 118 is 2 μm. Based on FIG. 17, it is known that the output capacitance Coss of the stripe type semiconductor cell structure 10 of FIG. 16 at the drain-source voltage of 1.2V is about 1595 pF, the output capacitance Coss of the stripe type semiconductor cell structure 200 of FIG. 5 at the drain-source voltage of 1.2V is about 1274 pF, and the output capacitance Coss of the stripe type semiconductor cell structure 300 of FIG. 6 at the drain-source voltage of 1.2V is about 1322 pF, so that by the disposition of the two stripe-shaped doping regions 118, the output capacitance Coss can be reduced about 20%, thereby improving the switching time. Thus, the stripe type semiconductor cell structure 200 and the stripe type semiconductor cell structure 300 with the disposition of the two stripe-shaped doping regions 118 are more suitable for the high frequency application.

In summary, in the embodiments of the present disclosure, by the disposition of the two stripe-shaped doping regions in the stripe type semiconductor cell structure (that is, the two stripe-shaped doping regions are disposed underneath the two stripe-shaped body contact regions respectively, the two stripe-shaped doping regions are arranged at a boundary between the drift layer and the current spreading layer, and the two stripe-shaped body contact regions are connected to at least a portion of the two stripe-shaped doping regions corresponding thereto), the output capacitance Coss of the stripe type semiconductor cell structure, which is linked to the extension of the depletion layer in the current spreading layer, is reduced when the Vds is low. Besides, by the zigzag patterns of the first doped regions and the second doped regions of the two alternating strips in the stripe type semiconductor cell structure and the configuration design of the adjacent stripe type semiconductor cell structures (that is, the adjacent stripe type semiconductor cell structures are arranged in a mirror image manner in the vertical direction), the semiconductor device and the stripe type semiconductor cell structure of the present disclosure can be provided with a uniform current distribution.

Although the present disclosure has been explained in relation to its preferred embodiment, it does not intend to limit the present disclosure. It will be apparent to those skilled in the art having regard to this present disclosure that other modifications of the exemplary embodiments beyond those embodiments specifically described here may be made without departing from the spirit of the disclosure. Accordingly, such modifications are considered within the scope of the disclosure as limited solely by the appended claims.

What is claimed is:

1. A stripe type semiconductor cell structure, comprising:
a semiconductor body comprising:
a drift layer of a first conductivity type;
a current spreading layer of the first conductivity type arranged on the drift layer;
spaced apart two well regions of a second conductivity type opposite to the first conductivity type arranged in the current spreading layer;
a junction gate field-effect transistor (JFET) region of the first conductivity type arranged in the current spreading layer and defined between the two well regions;
two source regions of the first conductivity type respectively disposed in the two well regions;
two stripe-shaped body contact regions of the second conductivity type respectively disposed in the two well regions; and
two stripe-shaped doping regions of the second conductivity type corresponding to the two stripe-shaped body contact regions, disposed underneath the two stripe-shaped body contact regions respectively, and arranged at a boundary between the drift layer and the current spreading layer, wherein the two stripe-shaped body contact region are connected to at least a portion of the two stripe-shaped doping regions corresponding thereto;
a stripe-shaped gate structure on the semiconductor body and arranged over the JFET region and at least portions of the two source regions; and
a drain electrode in contact with a surface of the semiconductor body away from the stripe-shaped gate structure.

2. The stripe type semiconductor cell structure according to claim 1, wherein a depth of each stripe-shaped doping region is greater than a depth of the current spreading layer.

3. The stripe type semiconductor cell structure according to claim 1, wherein each well region comprises a channel area, which is disposed under the stripe-shaped gate structure and next to the source region of the same well region and the JFET region; the two stripe-shaped doping regions are not underneath the two channel areas.

4. The stripe type semiconductor cell structure according to claim 1, wherein a doping concentration of each stripe-shaped doping region is higher than a doping concentration of the current spreading layer, and the doping concentration of each stripe-shaped doping region is lower than a doping concentration of each stripe-shaped body contact region.

5. The stripe type semiconductor cell structure according to claim 1, wherein a doping concentration of each stripe-shaped doping region is higher than a doping concentration of the drift layer, and the doping concentration of each stripe-shaped doping region is lower than a doping concentration of each stripe-shaped body contact region.

6. The stripe type semiconductor cell structure according to claim 1, wherein the two stripe-shaped body contact regions are located under the two source regions corresponding thereto.

7. The stripe type semiconductor cell structure according to claim 6, wherein the semiconductor body further comprises two alternating strips of first doped regions and second type doped regions; the two alternating strips are disposed in the two well regions respectively and on the two stripe-shaped body contact regions corresponding thereto, and are adjacent to the two source regions corresponding thereto.

8. The stripe type semiconductor cell structure according to claim 7, wherein the first doped regions of one of the two alternating strips and the first doped regions of another of the two alternating strips are arranged in a zigzag pattern, and the second doped regions of one of the two alternating strips and the second doped regions of another of the two alternating strips are arranged in a zigzag pattern.

9. The stripe type semiconductor cell structure according to claim 6, wherein the stripe-shaped gate structure is arranged over the two source regions.

10. The stripe type semiconductor cell structure according to claim 1, wherein the two stripe-shaped body contact regions surround a portion of the two source regions corresponding thereto.

11. The stripe type semiconductor cell structure according to claim 1, wherein the two source regions cover the two stripe-shaped body contact regions corresponding thereto.

12. The stripe type semiconductor cell structure according to claim 1, wherein the semiconductor body comprises two auxiliary doping source regions of the first conductivity type respectively disposed in the two well regions and located under the two source regions respectively, the two stripe-shaped body contact regions are located under the two auxiliary doping source regions respectively, and the stripe-shaped gate structure is arranged over the two source regions.

13. The stripe type semiconductor cell structure according to claim 1, wherein portions of the current spreading layer is interposed between portions of the two stripe-shaped doping region where they are not connected to the two stripe-shaped body contact regions and the two stripe-shaped body contact regions corresponding thereto.

14. The stripe type semiconductor cell structure according to claim 1, wherein the two stripe-shaped doping regions are fully connected to the two stripe-shaped body contact regions corresponding thereto.

15. The stripe type semiconductor cell structure according to claim 1, wherein the stripe-shaped gate structure comprises a gate dielectric layer arranged over the JFET region and the at least portions of the two source regions, and a gate electrode disposed on the gate dielectric layer.

16. A semiconductor device, comprising:
a plurality of stripe type semiconductor cell structures according to claim 8, and adjacent stripe type semiconductor cell structures are arranged in a mirror image manner in a vertical direction.
